(19) United States
(12) Patent Application Publication
(10) Pub. No.: US 2017/0261443 A1
(43) Pub. Date: Sep. 14, 2017

(54) Hand-Held Measuring Device having an NMR Sensor and Method for the Operation Thereof

(71) Applicant: Robert Bosch GmbH, Stuttgart (DE)

(72) Inventors: Reiner Krapf, Filderstadt (DE); Klaus Marx, Stuttgart (DE); Ulli Hoffmann, Niefern-Oeschelbronn (DE)

(21) Appl. No.: 15/506,287

(22) PCT Filed: Jul. 29, 2015
(86) PCT No.: PCT/EP2015/067368

§ 371 Date: Feb. 24, 2017

(30) Foreign Application Priority Data
Sep. 12, 2014 (DE) 10 2014 218 371.5

(51) Int. Cl. G01N 24/08; G01R 33/38

(52) U.S. Cl. CPC G01N 24/08; G01N 24/082; G01N 24/087; G01R 33/3808

(57) ABSTRACT

A mobile measuring device, in particular a hand-held measuring device, comprises a housing, in which at least one sensor device, a control device for controlling the sensor device, an evaluation device for evaluating the measurement signals supplied by the sensor device as well as a device for supplying energy to the measuring device are provided. The sensor device comprises at least one nuclear spin resonance sensor which is provided at least for the detection and/or analysis and/or differentiation of a material characteristic of a workpiece, in particular in a workpiece.

### PRIOR ART

The present invention relates to a mobile, in particular handheld measuring device, which has a housing, in which at least a sensor device, a control device for controlling the sensor device, an analysis device for analyzing measuring signals supplied by the sensor device, and a device for the power supply of the measuring device are provided.

A device for emitting and/or receiving electromagnetic high-frequency signals is known from DE 10 2005 062 874 A1, which enables locating and/or detecting of objects enclosed in a medium to be carried out by means of inductive sensors.

### DISCLOSURE OF THE INVENTION

The mobile measuring device, in particular handheld measuring device, according to the invention proceeds from a measuring device having a housing, in which at least a sensor device, a control device for controlling the sensor device, an analysis device for analyzing measuring signals supplied by the sensor device, and a device for the power supply of the measuring device are provided. According to the invention, the sensor device has at least one nuclear magnetic resonance sensor (NMR sensor), which is provided at least for detecting and/or analyzing and/or differentiating a material characteristic value of a workpiece, in particular a material characteristic value in a workpiece.

A handheld measuring device is to be understood here in particular to mean that the measuring device, without the aid of a transport machine, can be transported solely with the hands, in particular with one hand and in particular also can be guided along a workpiece during a measuring procedure. For this purpose, the mass of the handheld measuring device is in particular less than 5 kg, advantageously less than 3 kg, and particularly advantageously less than 1 kg. The measuring device can advantageously have a handle or a handle region, using which the measuring device can be guided over an object to be examined, in particular over a workpiece.

It is proposed that the components of the sensor device, the control device, the analysis device, and the device for the power supply of the measuring device be housed at least partially in the housing of the measuring device. In particular, the components have more than 50%, preferably more than 75%, and particularly preferably 100% of the total volume thereof housed in the housing of the measuring device. A compact measuring device which can easily be guided with one hand can thus advantageously be implemented. Furthermore, components may advantageously be protected in this manner from damage and environmental influences, for example, moisture and dust.

The mobile measuring device has a control device for controlling the sensor device. The control device is to be understood in particular as a device having at least one control electronics unit, which has means for communicating with the other components of the measuring device, for example, means for controlling and regulating the sensor device, and/or means for data processing and/or further means which appear advantageous to a person skilled in the art. In particular, the control device is provided for the purpose of setting at least one operating functional parameter of the measuring device depending on at least one user input and/or an analysis result of the analysis unit. “Provided” is to be understood especially as “programmed”, “designed”, and/or “equipped”. An object being “provided” for a specific function is to be understood to mean in particular that the object fulfills and/or executes this specific function in at least one application and/or operating state or is designed to fulfill the function. The control electronics unit of the control device according to the invention can advantageously be understood as a processor unit in conjunction with a memory unit and with an operating program stored in the memory unit, which is executed during the control procedure. In particular, the electronic components of the control device can be arranged on a circuit board (printed circuit board), preferably in the form of a microcontroller. The control device can particularly advantageously additionally be provided for controlling the entire measuring device and enabling its operation. For this purpose, the control device is provided for communicating with the other components of the measuring device, in particular the sensor device, the analysis device, an input and/or output device, and the data communication interface.

The analysis device for analyzing at least one measuring signal supplied by the sensor device is to be understood as at least one device which has an information input for accepting the measuring signals of the sensor device, an information processing unit for processing, in particular analyzing the accepted measuring signals, and also an information output for relaying the processed and/or analyzed measuring signals. The analysis unit advantageously has components which comprise at least one processor, a memory, and an operating program having analysis and calculation routines. In particular, the electronic components of the analysis device can be arranged on a circuit board (printed circuit board), preferably on a shared circuit board with the control device, particularly preferably in the form of a microcontroller. Furthermore, the control device and the analysis device can particularly preferably also be embodied as a single component. The analysis device is provided to analyze the measuring signals obtained from the sensor device and to derive therefrom at least items of information relating to detection and/or analysis and/or differentiation of material characteristic values in a workpiece, in particular material inclusions and/or objects in a workpiece.

Furthermore, the analysis device and/or the control device can have stored correction and/or calibration tables which enable analysis results to be interpreted and/or converted and/or interpolated and/or extrapolated and also the measuring device to be calibrated, in particular with respect to a workpiece material.

The device for the power supply of the measuring device is provided to supply the measuring device with electrical power for startup and during operation. This device is preferably a power-network-independent energy accumulator, in particular a rechargeable battery, a battery, a fuel cell, a capacitor, another type of energy accumulator which appears advantageous to a person skilled in the art, or a combination/plurality thereof. In particular rechargeable batteries having a cell chemistry which provides a high power and/or energy density are preferably suitable for the power supply of the measuring device. These presently include, for example, rechargeable batteries of the lithium and lithium-ion cell chemistry, in particular lithium-iron phosphate, lithium-manganese oxide, lithium-nickel-cobalt-manganese oxide, superlithiated lithium-nickel-cobalt-manganese oxide, lithium-sulfur, lithium-polymer, and lithium-oxygen rechargeable batteries. The device for power supply preferably has a detachable form-fitted and/or friction-locked connection interface. Detachable is to be understood as nondestructively disconnectable in particular in this context. The device for power supply can therefore preferably be arranged in a removable and replaceable manner on the measuring device. The removable device for power supply may particularly preferably be supplied and charged again with power from a power network in and/or outside the measuring device.

Material inclusions are to be understood in particular as inclusions or objects of different, metallic and/or nonmetallic materials in a material, in particular in the material of the workpiece. For example, wooden and steel inclusions in concrete, pipelines and cable lines in a wall, moisture in a concrete screed, but also cavities in a material represent such material inclusions.

A workpiece is to be understood in particular as coherent parts of a material. By way of example and not exhaustively, this can be a wall, a floor, a ceiling, screed, an organic structure (in particular parts of a body), and/or a part of a terrain in this case. For example, these materials can be made in particular of wood, glass, plastic, concrete, stone, brick, plaster, metal, organic materials, or the like. Furthermore, liquids may also be studied in principle.

According to the invention, the sensor device of the measuring device has at least one nuclear magnetic resonance sensor, which is provided at least for detecting and/or analyzing and/or differentiating material characteristic values in a workpiece. The functionality of the nuclear magnetic resonance sensor is based on the nuclear physics effect, in which atomic nuclei of a material sample, in particular in the workpiece, absorb and emit electromagnetic alternating fields in a magnetic field. In this case, the nuclear magnetic resonance is based on the precession (Larmor precession) of nuclear spins of the atomic nuclei in the material sample about the magnetic field lines of a constant, in particular static first magnetic field. In particular, the nuclear spins of the atomic nuclei in the material sample are aligned by the first magnetic field. If energy in the form of a second electromagnetic field, in particular an alternating field, for example, a pulsed magnetic field, is irradiated onto the atomic nuclei which is in resonance with the Larmor precession of the nuclear spins thereof (energy quanta), the atomic nuclei can thus change the orientation of the spins thereof in relation to the first magnetic field by absorption of this energy. The second irradiated magnetic field is therefore used to excite the nuclear spins, which changes the nuclear spin states thereof while absorbing energy. The emission of energy quanta as a consequence of a return of the excited nuclear spin into a different, lower energy level equivalently results in the emission of an electromagnetic alternating field, which may be observed by means of a device for detecting a magnetic field change, in particular by means of an antenna and/or a coil.

The nuclear magnetic resonance sensor advantageously enables atomic nuclei of the material sample in the workpiece to be excited by means of electromagnetic alternating fields and an output signal to be generated as a result of a nuclear spin resonance effect. With suitable selection of the operating parameters of the nuclear magnetic resonance sensor, material characteristic values, in particular material inclusions and/or material inhomogeneities, in the studied volume can be concluded directly by means of the amplitude and/or relaxation times of the response signal.

Excitation of atomic nuclei is to be understood in particular to mean that the energy of the irradiated electromagnetic fields, in particular alternating fields, causes a change of the nuclear spin of the atomic nuclei. Furthermore, it is presumed hereafter that in particular variable magnetic fields are coupled to electrical fields (cf. Maxwell equations), so that no differentiation is performed between electrical field and magnetic field. In particular the energy transmitted by irradiated electromagnetic radiation is important for the excitation of nuclear magnetic resonance effects. This energy may advantageously be transmitted by means of pulsed electromagnetic fields.

To carry out the measurement, the mobile measuring device, in particular the nuclear magnetic resonance sensor contained therein, is moved close to the workpiece to be examined.

“Detecting and/or analyzing and/or differentiating material characteristic values in a workpiece” is to be understood in particular to mean deriving statements from the obtained nuclear magnetic resonance measured data, which are analyzed, inter alia, for a relative and/or absolute hydrocarbon content and/or bonding states of chemical compounds and/or concentration gradients of a material in the workpiece and/or chronological-dynamic processes of chemical compounds and/or a relative and/or absolute moisture content and/or further construction-relevant parameters, in particular salt content, composition, and/or porosity of the material of the workpiece.

The mobile measuring device particularly advantageously enables the detection and/or analysis and/or determination of material characteristic values, in particular material inclusions and objects, in a workpiece without destruction of the workpiece. In particular, the measuring method is a nondestructive, in particular contactless measuring method, i.e., a material characteristic value can be obtained in one embodiment of the measuring device according to the invention even without any contact of the measuring device with the sample to be measured, possibly also without contact to the workpiece to be examined. The positioning of the measuring device, in particular the nuclear magnetic resonance sensor contained therein, in the immediate vicinity of the workpiece surface enables the examination of the workpiece down to a material depth of several centimeters into the workpiece. Essential target variables of the measuring device are the position, size, alignment, and depth of a material inclusion and/or a material inhomogeneity and/or an object in the workpiece.

For accurate measurement of workpieces, a calibration of the measuring device, in particular a calibration of the sensor device can be provided. For example, a calibration measurement can be carried out on a pure material sample (for example, pure metal), which is carried out after turning on the measuring device, to establish a maximum detectable concentration and therefore to calibrate the measuring device. All measurements which then follow, in particular measurements on a workpiece to be examined, are subsequently analyzed with reference to this calibration measurement. Furthermore, if the volume examined by means of the sensor device is known, an absolute value and volumetric variables, in particular a concentration, an item of volume-percent information, or the like can be analyzed.

In one advantageous embodiment of the measuring device according to the invention, an input device is provided for inputting operating parameters, in particular provided in the housing of the measuring device.

An input device is to be understood in particular as a means which is provided for the purpose of accepting at least one item of information from an operator of the measuring device (it is then in particular a user interface) and/or another device via an acoustic, optical, gesture-supported, and/or tactile input and relaying it to the control device of the measuring device.

For example, the input device can consist of an actuating element, a keyboard, a display screen, in particular a touch display screen, a speech input module, a gesture recognition unit, and/or a pointing device (for example, a mouse). Furthermore, the input device can additionally also be provided outside the measuring device, for example, in the form of an external data device such as a smartphone, a tablet PC, a PC, or in the form of another external data device which appears advantageous to a person skilled in the art and which is connected via a data communication interface to the control device of the measuring device.

Operating parameters refer to all necessary and/or advantageous operating parameters of the measuring device, in particular for the control thereof, and also parameters relating to the analysis of the measurement results.

In one advantageous embodiment of the mobile measuring device, an output device is provided for outputting operating parameters and/or analysis results, in particular provided in the housing of the measuring device.

An output device is to be understood as at least one means which is provided for outputting at least one changing item of information in an acoustic, optical, and/or tactile manner to an operator. This can be implemented, for example, by means of a display screen, a touch display screen, a sound signal, a change of an operating parameter, a vibration encoder, and/or an LED display. In particular, items of information to be output, for example, analysis results and/or items of information relating to an operating state of the measuring device, can also be output to a machine controller, in particular also to the control device of the sensor device, and/or, in particular to increase the user convenience, to a data processing system. The latter comprises at least one output of an item of information to an external device such as a smartphone, a tablet PC, a PC, and also to another external data device which appears advantageous to a person skilled in the art and which is connected via a data communication interface to the analysis device of the measuring device.

Therefore, both the input device and also the output device can thus advantageously be housed directly in the housing of the mobile measuring device or alternatively also can be outsourced and, for example, implemented via external devices. The latter implementation option explicitly comprises the control, analysis, and output of the measurement results via wired and/or wireless external systems such as, for example, remote controls, computer controllers, tablet PCs, and/or other mobile devices such as mobile telephones, smartphones, etc.

In one advantageous embodiment of the mobile measuring device, the input device and/or the output device are arranged on a first housing side of the measuring device. Housing side means in particular an outer wall of the housing delimiting the measuring device toward its environment. “Housed on a housing side” is to be understood to mean that the input device and/or the output device is/are inserted, applied, or fastened in another manner on the first housing side in the surface thereof. In particular, the housing itself can also be a component of the input and/or output device.

The first housing side advantageously faces toward the operator during the application of the measuring device.

In one advantageous embodiment of the mobile measuring device, the nuclear magnetic resonance sensor of the mobile measuring device has a first device for generating a first magnetic field, in particular a magnetic field having defined field gradients, a second device, in particular a high-frequency coil and/or an antenna, for generating a second magnetic field superimposed on the first magnetic field, wherein the control device has at least one control unit for controlling the second device, wherein the control unit is provided in particular for modifying the second magnetic field, in particular for generating pulse sequences.

The first magnetic field generated by the first device is used to align the nuclear spin of the atomic nuclei provided in the material of the workpiece in the sense that the nuclear spins align as a result of the magnetic nuclear spin moment thereof to the magnetic field lines of the magnetic field, and in particular process about the magnetic field lines of the magnetic field. An excitation of the nuclear spin occurs as a result of irradiation of energy in the form of an electromagnetic field generated by means of the second device, in particular an electromagnetic alternating field, for example, a pulsed magnetic field.

The first device for generating a first magnetic field, in particular having defined field gradients, can be understood in particular as devices such as permanent magnets, electromagnets, or coil devices. The magnetic field generated by the first device is typically identified with B₀.

The second device for generating a second magnetic field can be understood in principle as the same means, however, this second device is advantageously implemented by means of a high-frequency coil and/or an antenna. The high-frequency coil is particularly advantageously operated at a frequency in the megahertz range. In particular, the frequency is less than 900 MHz, preferably less than 200 MHz, and particularly preferably less than 50 MHz.

The control unit for controlling the second device, i.e., preferably for controlling the high-frequency coil, enables pulse sequences of the second magnetic field to be generated, so that the second magnetic field generated by the second device can be modified in a chronological and location-dependent manner. By means of the pulse sequences, the nuclear spins of the atomic nuclei of the material which is provided in the examined workpiece can particularly advantageously be excited, in particular to resonance, by electromagnetic alternating fields for the absorption and emission of energy quanta.

In one advantageous embodiment of the measuring device according to the invention, the nuclear magnetic resonance sensor has a device for detecting a magnetic field change, in particular a receiving coil for detecting a magnetic field change, which enables it to conclude material-specific characteristic variables by means of magnetic field changes caused by nuclear spin relaxation.

Using the device for detecting a magnetic field change, a nuclear magnetic resonance effect of the nuclear spins, which are provided and excited in the workpiece, of the atomic nuclei as a result of influencing of the first and/or the second magnetic field can advantageously be detected. Inversion of the nuclear spin of the atomic nuclei, upon which an electromagnetic field is emitted, can particularly advantageously be detected by means of a receiving coil in the form of a voltage induced by the magnetic field variation and/or an induced current. This voltage and/or this current can be relayed to the analysis device for analyzing the nuclear spin signal.

In an alternative embodiment of the measuring device according to the invention, the receiving coil can also be implemented by the high-frequency coil of the second device for generating the second magnetic field. In this case, the resonance of the nuclear spin of the atomic nuclei is noticeable in that an inversion of the nuclear spin, followed by an emission of an electromagnetic field, induces a voltage (equivalently: a current) in the coil, which is superimposed with the applied AC voltage, so that influences on the power required for operating the high-frequency coil can be detected.

In one particularly advantageous embodiment of the measuring device according to the invention, the first magnetic field generated by the first device of the nuclear magnetic resonance sensor is aligned substantially in parallel to a second housing side of the measuring device and the magnetic field generated by the second device is aligned substantially perpendicularly to the first magnetic field.

The second housing side is in particular a substantially planar outer wall of the housing which delimits the measuring device toward its surroundings. In particular, the second housing side faces toward the workpiece to be examined during application of the measuring device. The second housing side is advantageously on the device rear side, opposite to the first housing side which accommodates the input device and/or the output device, and therefore faces away from an operator during application of the measuring device.

The orientation of the first magnetic field can be generated by at least two permanent magnetic poles (north, south) of a permanent magnet, in particular if the poles are located in a north-south alignment in parallel to and in the vicinity of the second housing side. This arrangement may be implemented with a particularly simple structure by using a horseshoe magnet.

The first magnetic field, which is used to align the nuclear spins of the atomic nuclei provided in the material sample, in particular has a magnetic field strength of greater than 0.1 Tesla, preferably of greater than 1.5 Tesla, and particularly preferably of greater than 5 Tesla. In particular, strong permanent magnets are suitable for generating this magnetic field, for example, produced from ferrite or preferably as an iron-cobalt-nickel alloy or particularly preferably as a neodymium-iron-boron alloy or samarium-cobalt alloy.

Alternatively, the magnetic field alignment of the first magnetic field can be implemented by at least two permanent magnets, which are aligned perpendicularly to the surface of the second housing side of the measuring device in an antiparallel manner, in particular inside the housing, and are aligned in the vicinity of the second housing side. The magnetic field lines extending from the north pole of the first permanent magnet to the south pole of the second permanent magnet can be considered to be substantially parallel to the second housing surface of the measuring device, if the two permanent magnets are aligned at a distance from one another. In particular “substantially parallel” is to be understood to mean that a first region exists in which the magnetic field lines describing the first magnetic field can be considered to be nearly parallel. In particular in this first region, the deviation of the magnetic field lines from a theoretical parallel is less than 20°, advantageously less than 10°, and particularly advantageously less than 5°.

The second magnetic field, which extends substantially perpendicularly to the first magnetic field and therefore also to the second housing side, can be generated in one particularly advantageous embodiment using a coil and/or an antenna, in particular using a high-frequency coil. The coil is arranged for this purpose in particular in a plane parallel to and in the immediate vicinity of the surface of the second housing side, preferably in the interior of the housing, alternatively also externally on the housing or in the housing wall. The magnetic field lines of the magnetic field generated by the coil through which current flows extend perpendicularly to the plane of the coil in the vicinity of the coil. “Substantially perpendicularly to the first magnetic field” is to be understood here to mean that a second region exists in which the magnetic field lines describing the second magnetic field can be considered to be nearly perpendicular to the magnetic field lines of the first magnetic field. In particular, the angle deviation of the magnetic field lines of the first and the second magnetic fields from the perpendicular is less than 20°, advantageously less than 10°, and particularly advantageously less than 5°. The first and the second region are particularly advantageously coincident.

The magnetic field alignment of the first magnetic field can also be achieved by two permanent magnets arranged in parallel to the second housing side and in a collinear manner, i.e., in north-south/north-south sequence, wherein a high-frequency coil is located between these two permanent magnets, the winding plane of which is collinear to the extension direction of the permanent magnets and parallel to the second housing side. The described arrangement is also positioned in the vicinity of the second housing side in this case.

By way of suitable positioning of the devices for generating the magnetic fields in the vicinity of the second housing side, the region in which the two magnetic fields are superimposed is advantageously located at least partially outside the housing of the measuring device, so that an engagement of the magnetic fields in the workpiece to be examined is enabled.

In one alternative embodiment, the first magnetic field generated by the first device of the nuclear magnetic resonance sensor is aligned substantially perpendicularly to a second housing side of the measuring device and the second magnetic field generated by the second device is aligned substantially perpendicularly to the first magnetic field.

In one particularly advantageous embodiment of the measuring device according to the invention, the first device for generating the first magnetic field and/or the second device for generating the second magnetic field is/are at least partially enclosed by at least one magnetic shield.

This magnetic shield, which can consist in particular of ferromagnetic materials and/or Mu-metal and/or electrically conductive elements, enables influencing of the course of the magnetic field lines and therefore an optimization of the region in which the magnetic fields are superimposed. The latter means in particular a reduction or enlargement in size of the superposition region and/or a homogenization of the magnetic fields and/or a parallelization of the magnetic field lines and/or any arbitrary other influence of the magnetic field gradients of both magnetic fields.

Mu-metal (also: μ-metal) is to be understood as a soft-magnetic alloy of high magnetic permeability, which is usable for shielding magnetic fields.

This magnetic shield can particularly advantageously also be used to shield the magnetic fields used by the nuclear magnetic resonance sensor at least partially from other interfering influences, in particular electromagnetic radiation, and/or to shield components of the mobile measuring device itself at least partially in relation to electromagnetic radiation of the internal nuclear magnetic resonance sensor of the measuring device.

Furthermore, it is proposed that the nuclear magnetic resonance sensor have at least one device for homogenizing the magnetic fields generated by the first and/or second device.

Homogenization of a magnetic field is to be understood in particular to mean that the magnetic field lines describing the magnetic field and the local magnetic field strength thereof are subject to only slight, ideally no variations and in particular have no field distortions.

This device can be understood in particular as a coil, also called a shim coil, with the aid of which correction fields are generated, which are superimposed on the magnetic fields generated by the first and the second device and, in the event of suitable control, homogenize and/or influence them to a desired extent.

In one particularly advantageous embodiment of the mobile measuring device, the second device of the nuclear magnetic resonance sensor for generating the second magnetic field, in particular the high-frequency coil, is implemented as nondestructively replaceable.

In this manner, coils having different characteristics, in particular numbers of turns, geometry, and wire thicknesses, can be replaced nondestructively by a user of the measuring device and subsequently can be used. The magnetic fields generated by the second device can advantageously be varied and adapted to the required operating conditions, in particular the material of the workpiece to be examined, by suitable selection of the coil. Furthermore, the region in which the first and the second magnetic fields overlap can be displaced in its location and/or modified in its geometry.

To implement the replaceability, the measuring device can in particular have an access to the second device of the nuclear magnetic resonance sensor on the second housing side.

In one embodiment of the mobile measuring device, the magnetic fields of the nuclear magnetic resonance sensor define a first sensitive region of the nuclear magnetic resonance sensor, in particular a layered region, which extends substantially in parallel to and spaced apart from the second housing side outside the housing of the measuring device.

This sensitive region is located in particular in the superposition field of the first and the second magnetic fields. Depending on the frequency (Larmor frequency) of the irradiated electromagnetic field and the static magnetic field strength of the first magnetic field, the sensitive region is defined in the ideal case by an area on which the magnetic field strength of the first magnetic field is constant and in particular has a defined absolute value. In reality, the area is actually layered as a result of non-exact, i.e., non-discrete frequencies. Because furthermore the magnetic field lines do not extend exactly in parallel, the sensitive region can therefore be curved and/or inhomogeneous along the magnetic field lines, in particular inhomogeneous with respect to its layer extension.

In this manner, by means of positioning the mobile measuring device on a workpiece surface, wherein the second housing side of the measuring device is positioned in the immediate vicinity of the surface of the workpiece to be examined, the magnetic fields can particularly advantageously penetrate into the workpiece and the sensitive region of the nuclear magnetic resonance sensor can come to rest in the workpiece.

In one alternative and/or additional embodiment of the measuring device, the sensor device can be operated such that the sensitive region is located in the superposition field of the two magnetic fields inside the housing, in particular in the interior of the nuclear magnetic resonance sensor, preferably centrally between the two permanent magnetic poles spanning the first magnetic field. In this manner, a measuring device can be implemented with a simple design, into which material samples can be introduced for measuring. For example, in this manner material samples can be introduced into the measuring device by means of a sample tube through an opening in the second housing side of the measuring device such that they come to rest centrally between the two permanent magnetic poles spanning the first magnetic field and therefore in the sensitive region of the nuclear magnetic resonance sensor. It can particularly advantageously be provided that it is possible to switch over between the different arrangements of the sensitive region, in particular between a positioning of the sensitive region inside and outside the housing of the measuring device. Such switching over can advantageously be implemented mechanically (for example, by shielding and/or repositioning the first and/or the second device for generating the first or second magnetic field, respectively, in the measuring device) or electronically (for example, by changing the frequency in the high-frequency coil).

If the volume defined by the sensitive region, i.e., the volume of the material of the workpiece which is examined in a measurement, is known, absolute values and also in particular volumetric variables, for example, a concentration, an item of volume-percent information, or the like can be analyzed. The volume defined by the sensitive region can advantageously be known based on the design and/or by an apparatus measurement.

It is furthermore proposed that the sensitive region of the nuclear magnetic resonance sensor may be displaced along a perpendicular to the second housing side of the measuring device outside the housing, in particular mechanically and/or electronically, advantageously may be displaced by 1 cm, particularly advantageously by 2 cm, in particular by 3 cm.

The displacement of the sensitive region can advantageously be achieved in this case by modification of the magnetic fields, for example, by changing the geometry and/or homogeneity thereof by means of a coil (so-called shim coil) or a (movable) magnetic shield, particularly advantageously also by changing the frequency of the high-frequency coil, and by mechanically moving the nuclear magnetic resonance sensor in the housing of the measuring device. The sensitive region can therefore be displaced inside the workpiece with constant positioning of the measuring device such that a measurement having depth resolution can be implemented in a simple and particularly cost-effective manner.

In one particularly advantageous embodiment of the mobile measuring device according to the invention, the second housing side of the measuring device is arranged opposite to the first housing side accommodating the input device and/or the output device, and is in particular arranged on the rear side of the device.

In this manner, the measuring device, upon positioning having the sensitive region toward a workpiece, in particular having the second housing side adjoining the workpiece, can advantageously be operated via the input and/or output devices accommodated on the first housing side of the measuring device and/or measurement results can be read off.

It is proposed that in one further advantageous embodiment of the mobile measuring device, the analysis device is designed for analyzing measuring signals supplied by the sensor device and in particular is provided to analyze at least one amplitude and/or one relaxation time of a measuring signal, resulting from the excitation of nuclear spins in a workpiece by the magnetic field of the second device.

The analysis device is particularly advantageously designed for analyzing measuring signals supplied by the sensor device, at least one relative and/or absolute hydrocarbon content and/or bonding states of chemical compounds and/or concentration gradients of a material into the workpiece and/or chronological-dynamic processes of chemical compounds and/or a relative and/or absolute moisture content and/or further construction-relevant parameters, in particular salt content, composition, density, and/or porosity of the material of the workpiece, in particular for analyzing with depth resolution.

According to the invention, the mobile measuring device can therefore be used to comprehensively characterize a workpiece with respect to material characteristic values, in particular material inclusions and/or objects and/or material inhomogeneities. Statements about the relative and/or absolute hydrocarbon content and concentration gradients into the workpiece enable a reliable evaluation of a workpiece in particular with respect to processing capability (processing ability, drilling ability), strength, load-carrying capacity, and with respect to the presence of structurally different materials (inclusions) and the like.

Statements about the bonding states of the included material additionally enable it to be determined which form, in particular which material the material inclusion is. For example, inclusions such as metals, wood, and plastics may advantageously be detected and differentiated in this manner. Furthermore, statements can be made about included types of plastic and also, for example, statements about whether plastic pipes are filled with water.

Processes such as migration, convection, and travel of material inclusions can be studied with the recording and analysis of chronological-dynamic processes of chemical compounds. Conclusions about a possible flowing behavior may be derived therefrom.

The measuring device can also be used to comprehensively characterize a workpiece with respect to moisture. Statements about the relative and/or absolute moisture content and also about a moisture gradient into the workpiece enable a reliable evaluation of a workpiece in particular with respect to processing capability, dryness, risk of mold, strength, and/or load-carrying capacity. Analysis of chronological-dynamic processes of the water forming the moisture additionally enable the study of processes such as migration, convection, and travel of water, in particular of water fronts in the material, from which conclusions may be derived about possible drying or seepage behavior and/or a drying result.

Further construction-relevant parameters which can be analyzed using the analysis device of the mobile measuring device comprise in particular salt content, density, porosity, and/or inhomogeneity of the material of the workpiece, but also further parameters which appear advantageous to a person skilled in the art.

In a further advantageous embodiment of the mobile measuring device according to the invention, a position determination device is provided for capturing at least one instantaneous position and/or alignment of the measuring device, in particular in relation to the workpiece.

The position determination device can have in particular one or more sensors from a group of sensors, which comprises at least sensors sensitive to inclination, angle, distance, translation, acceleration, and rotation rate. Furthermore, a position determination can also be implemented using other means which appear advantageous to a person skilled in the art.

For example, the position determination device can be implemented using rolling bodies, in particular using wheels arranged on the housing of the measuring device, which record the position change upon movement of the measuring device in relation to the workpiece. Since the distance between measuring device and workpiece is preferably to be minimized to increase the penetration depth of the magnetic fields into the workpiece, the position determination device can particularly preferably also be provided as an optical distance transducer, which is arranged in the housing side facing toward the workpiece to be examined during application of the measuring device.

Furthermore, it is proposed that the analysis device for analyzing measuring signals supplied by the sensor device be designed for analyzing measuring signals of the sensor device as a function of the position and/or alignment of the measuring device, in particular in relation to the workpiece.

Analyzed parameters can therefore advantageously be correlated with a position of the measuring device on the workpiece. Furthermore, by successively measuring a workpiece, multidimensional matrices or maps in which measurement results of positions and/or alignments of the measuring device, in particular in relation to the workpiece, are captured, may be prepared and/or analyzed. This can particularly advantageously be used to generate a representation of the analyzed measuring signals in the form of a map of the workpiece.

In one embodiment of the measuring device, the analysis device for analyzing measuring signals supplied by the sensor device is particularly advantageously designed to carry out a detection of material inclusions on the basis of measuring signals of the sensor device, which relatively change as a function of the position and/or alignment of the measuring device, in particular in relation to the workpiece.

In this manner, material inclusions can be located particularly effectively and efficiently. In addition to the detection of material inclusions by means of determination of absolute measured values, the relative or comparative measurement, during which the measuring device can preferably be moved rapidly over a wall, enables locating of a material inclusion solely on the basis of position-dependent variations of the measuring signals supplied by the sensor device. Material inclusions concealed in the workpiece result, during the movement of the measuring device over the workpiece, in unambiguous, position-dependent signal changes, which stand out clearly in comparison to an otherwise relatively constant background signal of the remaining workpiece. Furthermore, the material, extension, and/or depth of the object found can be determined from the analysis of the measuring signals, for example, in particular with respect to change parameters, change dynamics, relaxation times, amplitudes, chemical shifts, etc. The information obtained in this manner may particularly advantageously be output as a two-dimensional, three-dimensional, or pseudo-four-dimensional map (for example, object profiles, depth profile, depth sectional images, etc.). Furthermore, a correlation of the results obtained by means of the comparative measurement to other measurement results can also take place.

In a further advantageous embodiment of the mobile measuring device, at least one memory device is provided for storing measurement results and/or operating parameters.

This memory device can comprise all forms of external and internal electronic, in particular digital memories, in particular also memory chips such as USB sticks, memory sticks, memory cards, etc.

In addition, it is proposed that the control device and/or the analysis device of the measuring device according to the invention have a data communication interface for in particular wireless communication, by means of which the measuring device can transmit and/or receive measurement results and/or operating parameters.

The data communication interface preferably uses a standardized communication protocol for a transmission of electronic, in particular digital data. The data communication interface advantageously comprises a wireless interface, in particular, for example, a WLAN, Bluetooth, infrared, NFC, or RFID interface or another wireless interface which appears advantageous to a person skilled in the art. Alternatively, the data communication interface can also have a wired adapter, for example, a USB or micro-USB adapter.

Advantageously, measurement results and/or operating parameters can be transmitted by means of the data communication interface from the measuring device to an external data device, for example, to a smartphone, a tablet PC, a PC, a printer, or further external devices which appear advantageous to a person skilled in the art, or received therefrom. By means of the embodiment according to the invention, a transmission of data can advantageously be enabled, which is usable for a further analysis of measuring signals captured using the measuring device. Furthermore, manifold auxiliary functions can advantageously be enabled and incorporated, which in particular also require direct communication with smartphones (in particular via programmed apps) or similar portable data devices. These can comprise, for example, automatic mapping functions, firmware updates, data postprocessing, data preparation, data comparison to other devices, etc.

Furthermore, it is proposed that the control device of the measuring device have an operating mode in which specifications on a workpiece can be specified by user inputs and/or provided to the measuring device.

An operating mode is to refer in particular to information processing, information output, or information input, in the context of which the control device applies an operating program, regulating routines, control routines, analysis routines, and/or calculation routines.

Specifications on a workpiece can relate, for example, to the material of the workpiece, the physical or chemical properties thereof, and arbitrary other specifications which appear advantageous to a person skilled in the art.

For one advantageous embodiment, it is proposed that the control device of the measuring device have an operating mode in which output parameters of the output device can be specified and/or provided to the measuring device.

Output parameters are to be understood as all specifications relating to the output, in particular characteristic variables of interest to the user, output forms (for example, as a number, graphic, map, converted equivalent variables), conversion options, error displays, correction factors, etc.

In a further embodiment of the measuring device according to the invention, the sensor device has at least one further sensor from a group of sensors which comprises at least sensors sensitive to induction, capacitance, ultrasound, temperature, radiation, inclination, angle, magnetic field, acceleration, rotation rate, and moisture.

In this manner, a combination of similar or complementary measuring instruments can advantageously be integrated into the measuring device according to the invention. For example, the nuclear magnetic resonance sensor may be expanded particularly advantageously using induction-sensitive and/or capacitance-sensitive sensors. The signals of the further sensors are preferably also analyzed by the analysis device for analyzing measuring signals supplied by the sensor device. The analysis results of the various sensors can advantageously be correlated with one another, in particular, measured values obtained by means of the further sensors can be used for correcting and/or optimizing and/or calibrating the measurement results ascertained by the nuclear magnetic resonance sensor.

Alternatively, an output of the further measurement results as a supplementary measured value and/or complementary value can also be performed by means of the output device.

According to the invention, a method for operating a measurement device is also proposed, in particular a method for detecting and/or differentiating and/or analyzing a material characteristic value of a workpiece, in particular a material characteristic value in a workpiece, which is characterized by at least the following steps:
generating a first magnetic field in the workpiece by means of a first device, which is arranged in the measuring device in particular,
generating high-frequency pulses in the workpiece by means of a second device of the measuring device, in particular by means of a high-frequency coil,
detecting at least one amplitude and/or a relaxation time of a measuring signal resulting from the excitation of nuclear spins in the workpiece, in particular by means of an electric current induced in a receiving coil and/or an induced voltage,
extracting Larmor frequencies from a measuring signal, in particular from an electric current induced in a receiving coil and/or a voltage induced in a receiving coil,
analyzing measuring signals of the nuclear magnetic resonance sensor to detect, differentiate, and/or analyze a material characteristic value of the workpiece, in particular a material characteristic value in a workpiece, by means of an analysis device, which is arranged in the measuring device in particular.

### DRAWINGS

The invention is explained in greater detail in the following description on the basis of exemplary embodiments illustrated in the drawings. The drawings, the description, and the claims contain numerous features in combination. A person skilled in the art will expediently also consider the features individually and combine them to form advantageous further combinations. Identical or similar reference signs in the figures identify identical or similar elements.

In the figures:

FIG. 1 shows a perspective illustration of one embodiment of the mobile measuring device according to the invention,

FIG. 2 shows a view of the first housing side of one embodiment of the measuring device according to the invention,

FIG. 3 shows a schematic side view of one embodiment of the measuring device according to the invention,

FIG. 4a shows a schematic and simplified illustration of one embodiment of the components forming the nuclear magnetic resonance sensor and the magnetic fields generated thereby,

FIG. 4b shows a schematic and simplified illustration of one alternative embodiment of the components forming the nuclear magnetic resonance sensor and the magnetic fields generated thereby,

FIG. 5 shows a perspective view of the second housing side of one embodiment of the mobile measuring device according to the invention.

### DESCRIPTION OF THE EXEMPLARY EMBODIMENTS

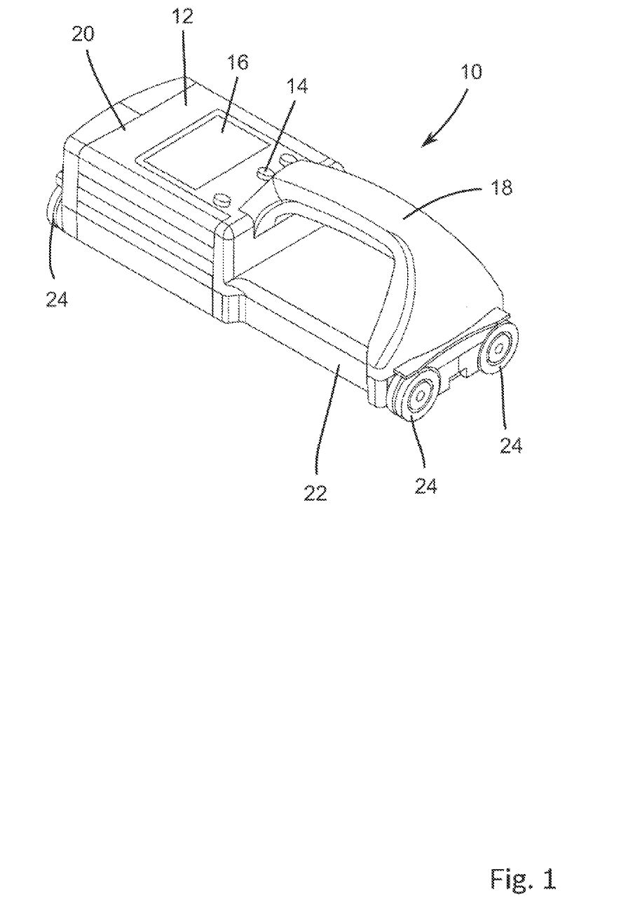

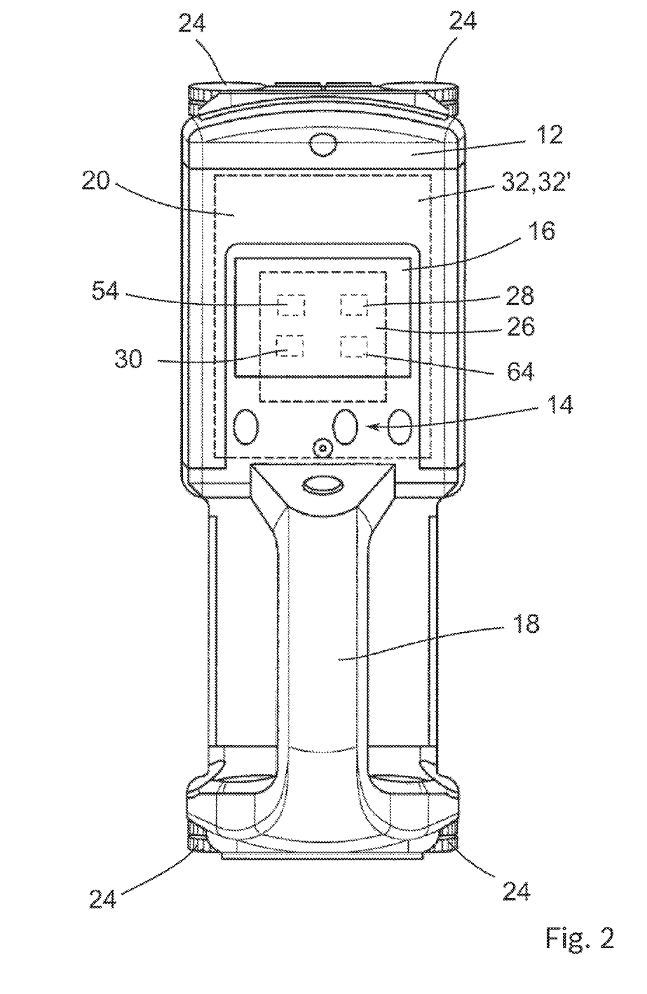

FIG. 1 and FIG. 2 show two views of one exemplary embodiment of the handheld measuring device 10 according to the invention in a perspective illustration and in a simplified, schematic view, respectively.

The handheld measuring device 10 embodied as an example has a housing 12, an input device in the form of actuating elements 14, suitable for turning the handheld measuring device on and off, for starting and configuring a measuring procedure, and for inputting operating parameters, and an output device for outputting operating parameters and/or analysis results in the form of a display screen 16. The handheld measuring device 10 has a handle 18 for transport and for the guiding thereof. The handle 18, the actuating elements 14, and the display screen 16 are located on a first housing side 20 of the measuring device 10 (also “front side”), which typically faces toward the user during operation of the measuring device.

For the power supply of the handheld measuring device 10, the device has a recess, which is preferably suitable for accommodating energy accumulators 22 independent of the power network, in particular batteries or rechargeable batteries, on the second housing side 40 (also referred to as the rear side of the measuring device hereafter), which is opposite to the first housing side 20 on the device rear side. The device presented as an example has lithium-ion rechargeable batteries, the high energy density and power density of which is advantageously suitable for the power supply of the measuring device. In one alternative embodiment, the energy accumulator 22 can also be housed in the handle 18 of the measuring device 10. The device for power supply advantageously has a detachable form-fitted and/or friction-locked connection interface, so that the energy accumulator 22 (generally a plurality thereof) can be arranged in a removable and replaceable manner. In addition, the energy accumulator 22 may also be supplied with power from a power network and charged in and/or outside the measuring device.

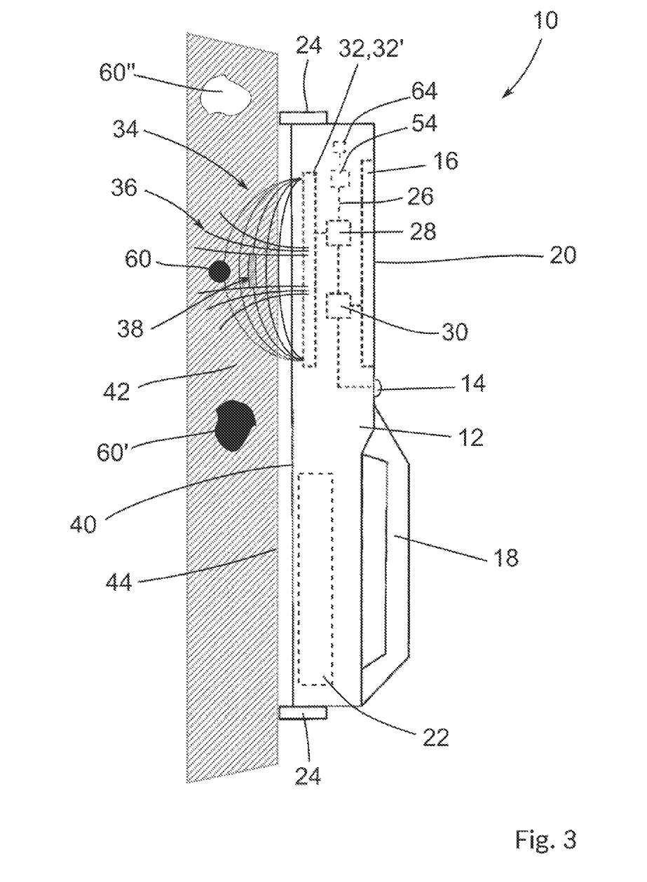

The position determination device of the handheld measuring device comprises, in the exemplary embodiment, four wheels 24, by means of which the handheld measuring device 10 can be moved along the surface 44 of a workpiece 42 (cf. FIG. 3). Sensors which are sensitive to a rotation of the wheels capture a movement of the measuring device 10 and therefore enable measurement results to be related to a position of the measuring device, in particular in relation to the workpiece 42. In one alternative embodiment of the measuring device 10, the position determination device can have an optical distance transducer instead of the wheels, for example. For more precise position determination, in addition further sensors can also be provided, in particular sensors sensitive to inclination, angle, translation, acceleration, and rotation rate. After placing the handheld measuring device 10 on the surface 44 of a workpiece 42 to be measured, for example, on a wall or on a concrete floor, the position change of the handheld measuring device as a consequence of a movement of the device on the workpiece is ascertained. These position data are relayed to an analysis device 30 for further analysis.

Further components of the measuring device, in particular a sensor device 32 having a nuclear magnetic resonance sensor 32′, a control device 28 for controlling the sensor device 32, an analysis device 30 for analyzing measuring signals supplied by the sensor device 32, and a data communication interface 54 connected to the control and/or analysis device are housed on a carrier element 26, in particular a system circuit board or printed circuit board inside the housing 12 (see in particular FIG. 2).

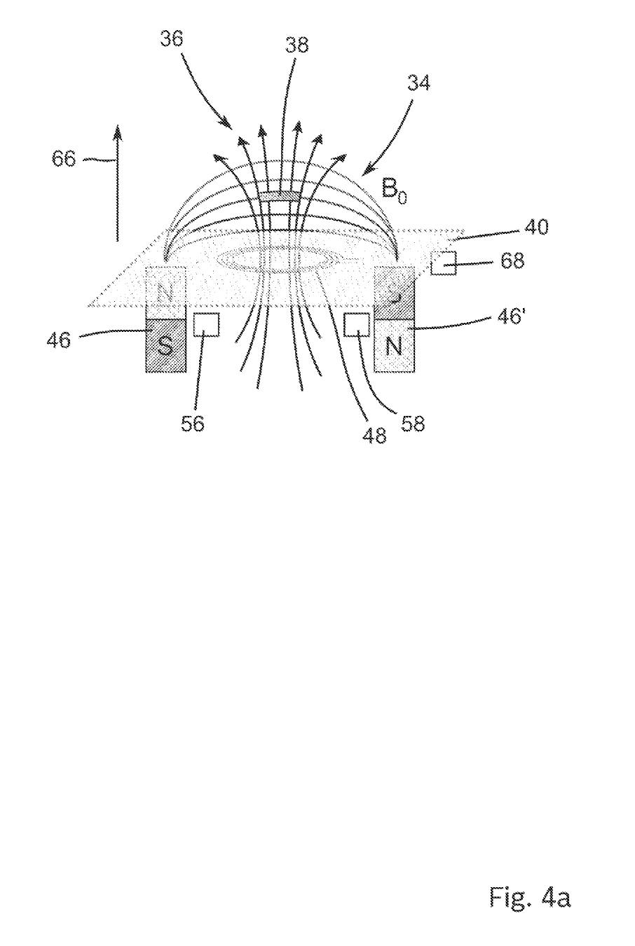

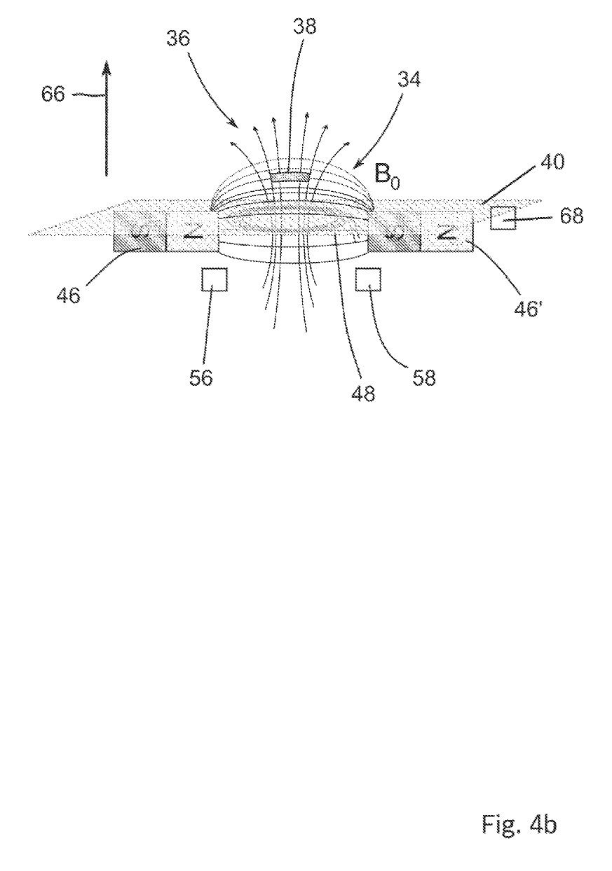

The nuclear magnetic resonance sensor 32′, which is explained in detail in FIGS. 4a and 4b, is provided for exciting nuclear magnetic resonance in atomic nuclei of the material of the workpiece 42. According to the invention, the measured resonance signal is used at least for the nondestructive detection and/or analysis and/or differentiation of a material characteristic value, in particular of material inclusions 60, 60′, 60″, in the workpiece 42, i.e., for ascertaining items of information which relate, inter alia, to a relative and/or absolute hydrocarbon content and/or bonding states of chemical compounds and/or concentration gradients of a material into the workpiece and/or chronological-dynamic processes of chemical compounds and/or a relative and/or absolute moisture content and/or further construction-relevant parameters, in particular salt content, composition, and/or porosity of the material of the workpiece. The control device 28 has a control electronics unit comprising means for communication with the other components of the measuring device, for example, means for controlling and regulating the sensor device 32 and the measuring device. The control device 28 comprises in particular a unit having a processor unit, a memory unit, and an operating program stored in the memory unit. The control device 28 is provided for the purpose of setting at least one operating functional parameter of the measuring device depending on at least one input by the user, by the analysis device, and/or by the data communication interface.

The analysis device 30 for analyzing measuring signals supplied by the sensor device 32, optionally also for analyzing measuring signals of further sensor devices of the handheld measuring device 10, has in particular an information input, an information processing unit, and an information output. The analysis device 30 advantageously at least consists of a processor, a memory having an operating program stored and executable thereon, and enables at least one measuring signal of the nuclear magnetic resonance sensor 32′ to be analyzed and items of information to be determined with respect to the detection and/or analysis and/or differentiation of material inclusions 60, 60′, 60″ in a workpiece. The analysis device particularly advantageously has stored correction and/or calibration tables, which enable the analysis results to be interpreted, converted, interpolated and/or extrapolated, and also the measuring device, in particular the analysis routines, to be calibrated with respect to a workpiece material. The analysis results are output by the analysis device 30 for further use via the control device 28 either directly to a user of the measuring device 10 or for transmitting the data to the data communication interface 54.

For the measurement of a nuclear magnetic resonance signal of a workpiece 42, in particular for the detection and/or analysis and/or differentiation of material inclusions 60, 60′, 60″ in this workpiece, the measuring device 10 is positioned having its second housing side 40, i.e., the device rear side, in a planar manner in the immediate vicinity of the workpiece 42, in particular in contact with the surface 44 thereof. In this case, the magnetic fields 34, 36 generated by the nuclear magnetic resonance sensor 32′ penetrate through the second housing side 40 out of the measuring device 10 and into the workpiece 42, wherein the sensitive region 38 comes to rest in the workpiece (see in particular FIG. 3). Magnetic field changes as a result of a nuclear magnetic resonance effect of the nuclear spins of the atomic nuclei excited in the material of the workpiece 42, i.e., caused by absorption and/or emission of electromagnetic fields by the atomic nuclei accompanied by a change of the energy states thereof, can be detected by means of a receiving coil 68 of the nuclear magnetic resonance sensor 32′. This measuring signal, in particular the amplitude and relaxation times thereof, is relayed to the analysis device 30, by which it is analyzed and prepared by means of analysis routines and relayed to an output device 16. The analyzed measurement result is displayed to the user on the display screen 16 and can alternatively be transmitted via the data communication interface 54 to a further data processing device. The output on the display screen 16 can be graphic, numeric, and/or alphanumeric, for example, in the form of a measured value, a measuring curve, a signal curve, a time curve, as image data, or in a gradient representation and also in a combination thereof. Alternatively or additionally, a display is possible by means of a signal display, in particular, for example, a light-emitting diode which evaluates a target variable via a color coding, for example (for example, red, yellow, green).

The positioning of the measuring device 10, in particular the nuclear magnetic resonance sensor 32′ contained therein, in the immediate vicinity of the workpiece surface enables the detection and/or analysis and/or differentiation of material inclusions 60, 60′, 60″ to a material depth of several centimeters into the workpiece 42.

FIG. 3 shows the embodiment according to the invention of the handheld measuring device 10 of FIGS. 1 and 2 in a simplified schematic side view. The nuclear magnetic resonance sensor 32′ comprises two devices for generating magnetic fields, in particular a permanent magnet arrangement 46, 46′ (cf. FIG. 4a), which generates a first magnetic field 34, and a high-frequency coil 48 (cf. FIG. 4a), which generates a second magnetic field 36. The nuclear magnetic resonance sensor 32′ is configured such that the first magnetic field 34 is aligned substantially in parallel to the second housing side 40, while the second magnetic field 36 is aligned substantially perpendicularly to the magnetic field lines of the first magnetic field 34. The two magnetic fields are superimposed in an extended region in which in particular the sensitive region 38 of the nuclear magnetic resonance sensor 32′ is also located, as a layered region in particular. The handheld measuring device 10 is positioned having the second housing side 40 in the immediate vicinity of a workpiece 42 to be examined, so that the distance between the second housing side 40 and the workpiece surface 44 is minimized. In this manner, the magnetic fields 34, 36 penetrate into the workpiece and the sensitive region 38 comes to rest in the workpiece 42.

By variation of the second magnetic field 36 generated by the second device, i.e., in particular by variation of the high-frequency coil 48 and/or variation of the frequency and/or variation of the current and/or variation of the voltage in the high-frequency coil 48, it is possible to change the sensitive region 38 in its distance to the second housing side 40 and therefore to modify the distance of the sensitive region 38 in the workpiece to the workpiece surface 44 thereof. Alternatively and/or additionally, the nuclear magnetic resonance sensor 32′ can be repositioned in the housing 12 of the handheld measuring device 10 such that the distance of the nuclear magnetic resonance sensor 32′ to the second housing side 40 is changed and therefore the distance of the sensitive region 38 in the workpiece 42 to the workpiece surface 44 thereof is also changed. In this manner, depth profiles of the parameters to be analyzed, in particular material concentration depth profiles, may be particularly advantageously prepared. For example, it is possible to make a statement about the permissible drilling depth into the workpiece 42 via a depth profile of a material inclusion 60, 60′, 60″ to be detected in a workpiece 42, before the material inclusion 60, 60′, 60″ is encountered.

FIG. 4a shows a simplified and schematic illustration of the components of one embodiment of the nuclear magnetic resonance sensor 32′ according to the invention. Two permanent magnets 46, 46′, which are arranged perpendicularly to the second housing side 40 and antiparallel to one another, generate a first, in particular static magnetic field 34, which extends substantially in parallel to the surface of the second housing side 40. This first magnetic field, which is provided for aligning the nuclear spins of the atomic nuclei provided in the material sample, has, for example, in particular a magnetic field strength of 0.5 Tesla, wherein the permanent magnets are produced from a neodymium-iron-boron alloy. The second device for generating the second magnetic field is formed in this exemplary embodiment by a high-frequency coil 48. As soon as current flows through this coil, an electromagnetic field, in particular the second magnetic field 36, is induced. The two magnetic fields are superimposed in a region which is located substantially outside the housing 12 of the measuring device 10. The sensitive region 38 of the nuclear magnetic resonance sensor 32′ is also in the superposition field of the magnetic fields 34 and 36. As a function of the frequency of the irradiated electromagnetic field 36 and the static magnetic field strength of the first magnetic field 34, the sensitive region is defined in the ideal case by an area, on which the magnetic field strength of the first magnetic field 34 is constant and in particular has a defined absolute value. In reality, the area is actually layered as a result of inexact frequencies. Because the magnetic field lines 34 do not extend exactly in parallel to the second housing side 40, the sensitive region 38 is therefore also curved in accordance with the magnetic field lines. The curvature and formation of the first magnetic field 34 and therefore of the sensitive region 38 can be influenced and in particular homogenized using further means, for example, a shim coil 56 and a magnetic shield 58.

FIG. 4b shows a simplified and schematic illustration of the components of an alternative embodiment of the nuclear magnetic resonance sensor 32′ according to the invention. In this case, the first, in particular static magnetic field 34, which is generated by the first device, two permanent magnets 46, 46′ arranged in parallel to the second housing side and collinearly here (in north-south/north-south sequence), is aligned substantially in parallel to a second housing side 40 of the measuring device 10 and the second magnetic field 36, which is generated by the second device, a high-frequency coil 48 here, is aligned substantially perpendicularly to the first magnetic field 34. A high-frequency coil 48, the winding plane of which is collinear to the extension direction of the permanent magnets 46, 46′ and parallel to the second housing side 40, is located between the two permanent magnets 46, 46′. This arrangement is positioned in the immediate vicinity of the second housing side 40. As soon as current flows through this coil, an electromagnetic field, in particular the second magnetic field 36, is induced. The two magnetic fields are superimposed in a region which is located substantially outside the housing 12 of the measuring device 10. The sensitive region 38 of the nuclear magnetic resonance sensor 32′ is also located in the superposition field of the magnetic fields 34 and 36. As a function of the frequency of the irradiated electromagnetic field 36 and the static magnetic field strength of the first magnetic field 34, the sensitive region is defined in the ideal case by an area, on which the magnetic field strength of the first magnetic field 34 is constant and in particular has a defined absolute value. In reality, the area is actually layered as a result of inexact frequencies. Because the magnetic field lines 34 do not extend exactly in parallel to the second housing side 40, the sensitive region 38 is therefore also curved in accordance with the magnetic field lines. The curvature and formation of the first magnetic field 34 and therefore of the sensitive region 38 can be influenced and in particular homogenized using further means, for example, a shim coil 56 and a magnetic shield 58.

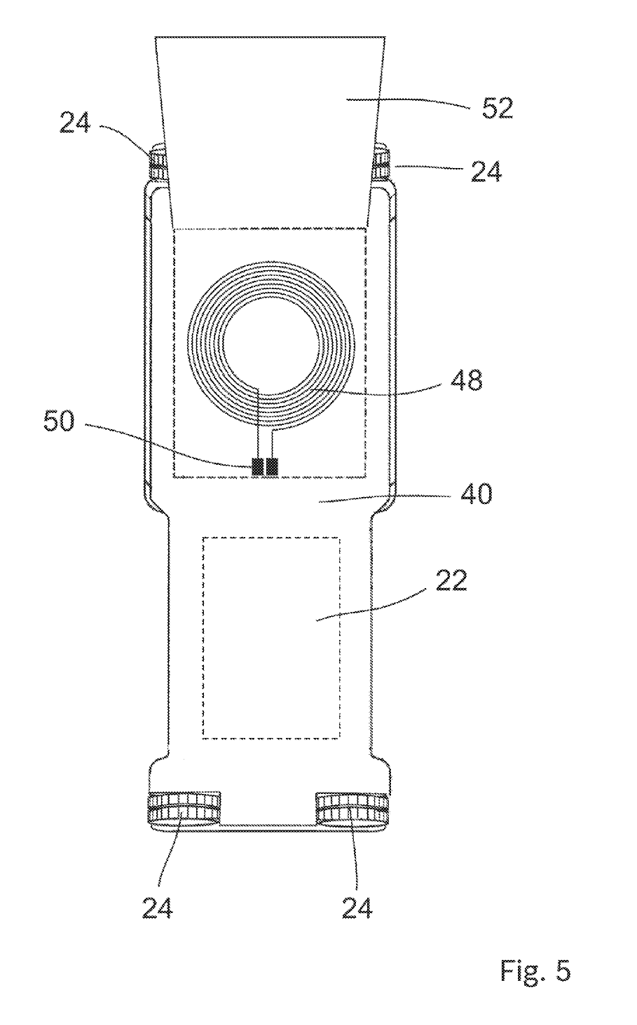

FIG. 5 shows a perspective, simplified illustration of a top view of the second housing side 40, i.e., the rear side of the handheld measuring device 10. The receptacle of the energy accumulator 22, in particular a battery or a rechargeable battery, is directly accessible under a housing flap (dashed lines) on this second housing side 40. A second housing flap 52, shown open in the figure, enables the access to the high-frequency coil 48. The connection plugs 50 of the high-frequency coil 48 are particularly advantageously embodied as detachable, i.e., in particular nondestructively disconnectable. In this manner, the high-frequency coil 48 is replaceable with high-frequency coils having a different characteristic, i.e., which differ in particular with respect to the number of turns, type of turns, geometry, and wire thickness thereof. This possibility for the variation of the high-frequency coil 48 advantageously enables the second magnetic field 36 generated by the high-frequency coil 48 to be modified and in particular to be adapted and optimized to the conditions of the workpiece material. In this simplified illustration, the further components of the nuclear magnetic resonance sensor 32′ from FIG. 4a are not shown.

1. A mobile measuring device, comprising:
a housing;
a sensor device at least partially located in the housing;
a control device configured to control the sensor device;
an analysis device configured to analyze measuring signals supplied by the sensor device; and
a device for a power supply of the measuring device,
wherein the sensor device has at least one nuclear magnetic resonance sensor configured to detect, analyze, and/or differentiate a material characteristic value of a workpiece.

2. The measuring device as claimed in claim 1, further comprising:
an input device configured to input operating parameters.

3. The measuring device as claimed in claim 2, further comprising:
an output device configured to output operating parameters and/or analysis results.

4. The measuring device as claimed in claim 3, wherein at least one of the input device and the output device is arranged on a first housing side.

5. The measuring device as claimed in claim 1, wherein the nuclear magnetic resonance sensor has a receiving coil configured to detect a magnetic field change.

6. The measuring device as claimed in claim 4, wherein:
the nuclear magnetic resonance sensor has a first device configured to generate a first magnetic field and a second device configured to generate a second magnetic field,
the second magnetic field is superimposed on the first magnetic field,
the control device has at least one control unit configured to control the second device, and
the control unit is configured to modify the second magnetic field to generate pulse sequences.

7. The measuring device as claimed in claim 6, wherein:
the first magnetic field is aligned substantially in parallel to a second housing side of the measuring device, and
the second magnetic field is aligned substantially perpendicularly to the first magnetic field.

8. The measuring device as claimed in claim 6, wherein:
at least one of the first device and the second device is at least partially enclosed by at least one magnetic shield, and
the nuclear magnetic resonance sensor has at least one homogenizing device configured to homogenize the magnetic fields generated by the first and/or the second device.

9. (canceled)

10. The measuring device as claimed in claim 6, wherein:
the second device is implemented as nondestructively replaceable and includes a high frequency coil.

11. The measuring device as claimed in claim 6, wherein the first and second magnetic fields define a sensitive region of the nuclear magnetic resonance sensor extending substantially in parallel to and spaced apart from a second housing side outside the housing of the measuring device.

12. The measuring device as claimed in claim 11, wherein the sensitive region of the nuclear magnetic resonance sensor is displaceable perpendicularly to the second housing side of the measuring device outside the housing by 1 cm to 3 cm.

13. The measuring device as claimed in claim 11, wherein the second housing side of the measuring device is opposite to the first housing side accommodating the input device and/or the output device on a rear side of the device.

14. The measuring device as claimed in claim 6, wherein the analysis device is configured to analyze at least one amplitude and/or the measuring signal supplied by the sensor device resulting from the excitation of the nuclear spins in a workpiece by the second magnetic field.

15. The measuring device as claimed in claim 14, wherein the analysis device analyzes the measuring signals supplied by the sensor device, at least to determine:
a relative and/or absolute hydrocarbon content;
bonding states of chemical compounds;
concentration gradients of a material into the workpiece;
chronological-dynamic processes of chemical compounds;
a relative and/or absolute moisture content; and/or
further construction-relevant parameters including salt content, composition, and/or porosity of the material of the workpiece with depth resolution.

16. The measuring device as claimed in claim 1, further comprising:
a position determination device configured to capture at least one instantaneous position and/or alignment of the measuring device in relation to the workpiece; and
at least one memory device configured to store measurement results and/or operating parameters.

17. The measuring device as claimed in claim 16, wherein:
the analysis device is configured to analyze the measuring signals of the sensor device as a function of a position and/or alignment of the measuring device in relation to the workpiece, and
the analysis device is further configured to carry out the detection, the analysis, and/or the differentiation of the material characteristic value based on measuring signals of the sensor device which relatively change as a function of the position and/or the alignment of the measuring device in relation to the workpiece.

18. (canceled)

19. (canceled)

20. The measuring device as claimed in claim 1, wherein the control device and/or the analysis device has a data communication interface configured for wireless communication to enable the measuring device to transmit and/or to receive measurement results and/or operating parameters.

21. The measuring device as claimed in claim 3, wherein:
the control device has a first operating mode, in which specifications on a workpiece are specified by user inputs and/or provided to the measuring device, and
the control device has a second operating mode, in which output parameters of the output device are specified and/or provided to the measuring device.

22. (canceled)

23. The measuring device as claimed in claim 1, wherein the sensor device comprises at least one further sensor from a group of sensors which comprises at least sensors sensitive to induction, capacitance, ultrasound, temperature, radiation, inclination, angle, magnetic field, acceleration, rotation rate, and moisture.

24. A method for detecting, differentiating, and/or analyzing a material characteristic value in a workpiece comprising:
generating a first magnetic field in the workpiece with a first device arranged in the measuring device;
generating high-frequency pulses in the workpiece with a second device of the measuring device, the second device including a high-frequency coil;
detecting at least one amplitude and/or a relaxation time of a measuring signal resulting from the excitation of nuclear spins in the workpiece based on an electric current induced in a receiving coil and/or an induced voltage;
extracting Larmor frequencies from the measuring signal induced in the receiving coil; and
analyzing measuring signals of the nuclear magnetic resonance sensor for the differentiation and/or the analysis of the material characteristic value in the workpiece with an analysis device of the measuring device.
